(19) United States
(12) Patent Application Publication
(10) Pub. No.: US 2026/0080916 A1
(43) Pub. Date: Mar. 19, 2026

(54) SEMICONDUCTOR MEMORY DEVICE AND METHOD FOR MANUFACTURING THE SEMICONDUCTOR MEMORY DEVICE

(71) Applicant: Kioxia Corporation, Tokyo (JP)

(72) Inventors: Sho MORITA, Kuwana (JP); Noritaka ISHIHARA, Nagoya (JP)

(73) Assignee: Kioxia Corporation, Tokyo (JP)

(21) Appl. No.: 19/074,813

(22) Filed: Mar. 10, 2025

(30) Foreign Application Priority Data
Sep. 18, 2024 (JP) 2024-160739

(51) Int. Cl. G11C 5/06; H10B 43/10; H10B 43/27

(52) U.S. Cl. CPC G11C 5/063; H10B 43/10; H10B 43/27

(57) ABSTRACT

According to one embodiment, a semiconductor memory device includes a stacked body in which a plurality of conductive layers and a plurality of insulating layers are alternately stacked one by one, and a pillar extending in the stacked body in a stacking direction of the stacked body, in which the pillar includes a first semiconductor layer extending in the stacked body in the stacking direction, and a second semiconductor layer that extends in the stacked body in the stacking direction and includes more grain boundaries than grain boundaries of the first semiconductor layer, and an additive having a peak concentration at an interface between the first semiconductor layer and the second semiconductor layer is included.

### CROSS-REFERENCE TO RELATED APPLICATIONS

This application is based upon and claims the benefit of priority from Japanese Patent Application No. 2024-160739, filed on Sep. 18, 2024; the entire contents of which are incorporated herein by reference.

### FIELD

Embodiments described herein relate generally to a semiconductor memory device and a method for manufacturing the semiconductor memory device.

### BACKGROUND

In a three-dimensional nonvolatile memory, a plurality of memory cells each having a channel layer on a side surface of a pillar extending in a height direction is arranged along the height direction of the pillar. In the three-dimensional nonvolatile memory, improvement in operation characteristics of the memory cells is desired.

### BRIEF DESCRIPTION OF THE DRAWINGS

FIGS. 1A and 1B are diagrams illustrating a schematic configuration example of a semiconductor memory device according to an embodiment;

FIGS. 2A to 2C are cross-sectional views illustrating an example of a configuration of the semiconductor memory device according to the embodiment;

FIGS. 3A to 3C are diagrams sequentially illustrating some procedures of a method for manufacturing the semiconductor memory device according to the embodiment;

FIGS. 4A and 4B are diagrams sequentially illustrating some procedures of the method for manufacturing the semiconductor memory device according to the embodiment;

FIGS. 5A and 5B are diagrams sequentially illustrating some procedures of the method for manufacturing the semiconductor memory device according to the embodiment;

FIGS. 6A and 6B are diagrams sequentially illustrating some procedures of the method for manufacturing the semiconductor memory device according to the embodiment;

FIGS. 7A to 7I are diagrams sequentially illustrating some procedures of the method for manufacturing the semiconductor memory device according to the embodiment;

FIGS. 8A and 8B are diagrams sequentially illustrating some procedures of the method for manufacturing the semiconductor memory device according to the embodiment;

FIGS. 9A and 9B are diagrams sequentially illustrating some procedures of the method for manufacturing the semiconductor memory device according to the embodiment;

FIGS. 10A and 10B are diagrams sequentially illustrating some procedures of the method for manufacturing the semiconductor memory device according to the embodiment;

FIGS. 11A and 11B are diagrams sequentially illustrating some procedures of the method for manufacturing the semiconductor memory device according to the embodiment;

FIGS. 12A and 12B are diagrams sequentially illustrating some procedures of the method for manufacturing the semiconductor memory device according to the embodiment;

FIGS. 13A and 13B are partially enlarged cross-sectional views of pillars included in a semiconductor memory device according to a modification to the embodiment; and

FIGS. 14A to 14C are diagrams illustrating some procedures of the method for manufacturing the semiconductor memory device according to the modification to the embodiment.

### DETAILED DESCRIPTION

In general, according to one embodiment, a semiconductor memory device includes a stacked body in which a plurality of conductive layers and a plurality of insulating layers are alternately stacked one by one; a pillar extending in the stacked body in a stacking direction of the stacked body, in which the pillar includes a first semiconductor layer extending in the stacked body in the stacking direction, and a second semiconductor layer that extends in the stacked body in the stacking direction and includes more grain boundaries than grain boundaries of the first semiconductor layer, and an additive having a peak concentration at an interface between the first semiconductor layer and the second semiconductor layer.

Hereinafter, an exemplary embodiment of the present invention will be described in detail with reference to the drawings. It is noted that the present invention is not limited to the embodiment described below. The elements in the following embodiment include elements that can be easily assumed by those skilled in the art or those that are substantially the same.

### Embodiment

Hereinafter, an embodiment will be described in detail with reference to the drawings.

### Configuration Example of Semiconductor Memory Device

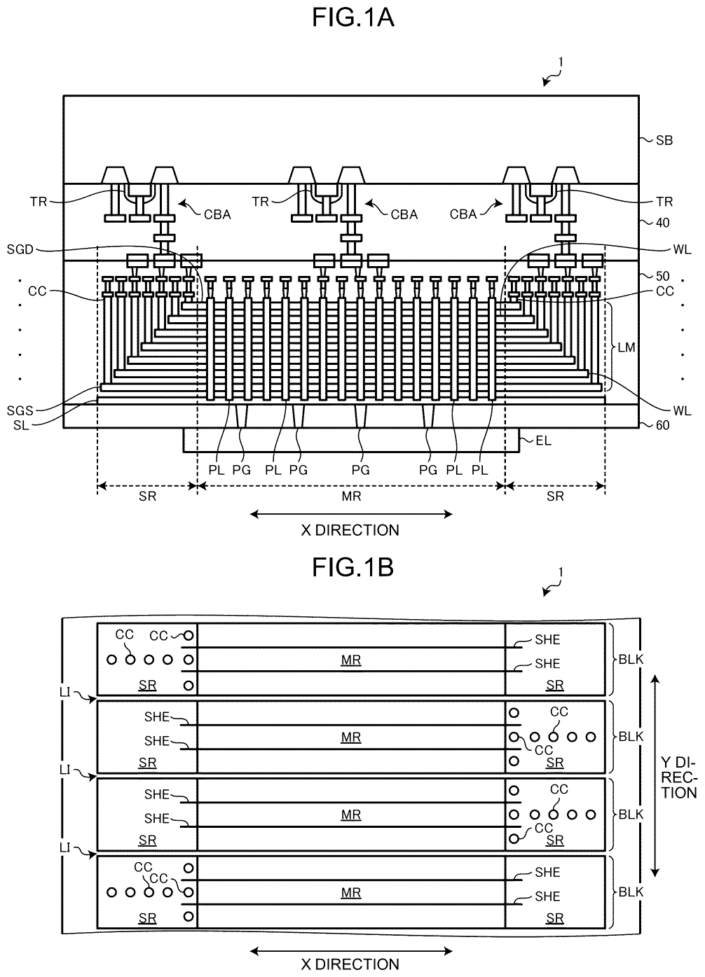

FIGS. 1A and 1B are diagrams illustrating a schematic configuration example of a semiconductor memory device 1 according to the embodiment. More specifically, FIG. 1A is a cross-sectional view of the semiconductor memory device 1 along the X direction, and FIG. 1B is a schematic plan view illustrating a layout of the semiconductor memory device 1.

Meanwhile, in FIG. 1A, hatching is omitted for the sake of clarity in the drawing. Further, in FIG. 1A, configurations that do not necessarily exist on the same cross section are illustrated, and a part of upper layer wiring and the like are omitted.

In the present specification, both the X direction and the Y direction are directions along the orientation of planes of word lines WL, and the X direction and the Y direction are orthogonal to each other. Further, an electrical drawing direction of the word line WL is sometimes referred to as a first direction. The first direction is a direction along the X direction. In addition, a direction intersecting the first direction is sometimes referred to as a second direction. The second direction is a direction along the Y direction. However, the first direction and the second direction are not necessarily orthogonal to each other because there may be a manufacturing error in the semiconductor memory device 1.

As illustrated in FIG. 1A, the semiconductor memory device 1 includes a semiconductor substrate SB on which an electrode film EL, a source line SL, one or more select gate lines SGS, a plurality of word lines WL, one or more select gate lines SGD, and a peripheral circuit CBA are provided in order from the lower side of the drawing.

The source line SL is disposed above the electrode film EL via an insulating layer 60. A plurality of plugs PG is disposed in the insulating layer 60, and the source line SL and the electrode film EL are electrically conducted via the plugs PG. Although not illustrated, an electrode pad for supplying power and a signal from the outside to the semiconductor memory device 1 is provided in the same layer as the electrode film EL. On the source line SL, the select gate line SGS, the plurality of word lines WL, and the select gate line SGD are stacked in this order.

As illustrated in FIGS. 1A and 1B, memory regions MR are disposed at the center in the X direction of the plurality of word lines WL and the like, and staircase regions SR are disposed at both ends in the X direction of the plurality of word lines WL and the like. The memory regions MR and the staircase regions SR are divided into a plurality of regions by a plurality of plate-like contacts LI extending in the direction along the X direction through the plurality of word lines WL and the like.

A region that is disposed between the plate-like contacts LI adjacent in the Y direction and includes the memory region MR and the staircase regions SR is referred to as a block region BLK. As will be described later, the memory region MR includes a plurality of memory cells that stores data in a nonvolatile manner, and the block region BLK is an erase unit for the data.

Between the plate-like contacts LI adjacent in the Y direction, a plurality of separation layers SHE extending through the select gate line SGD in the direction along the X direction is disposed. The plurality of separation layers SHE extends over the entire memory region MR in the direction along the X direction to reach a part of the staircase regions SR at both ends in the X direction.

In the memory region MR, a plurality of pillars PL penetrating the word lines WL and the select gate lines SGD and SGS in the stacking direction thereof is disposed. The lower ends of the pillars PL reach the source line SL. A plurality of memory cells is formed at an intersection of the pillar PL and the word line WL. Thereby, the semiconductor memory device 1 is configured as, for example, a three-dimensional nonvolatile memory including the memory cells arranged three-dimensionally in the memory region MR.

In the staircase regions SR, the plurality of word lines WL and the select gate lines SGD and SGS are processed stepwise and terminate. At this time, as the distance from the memory region MR increases in the X direction, the plurality of word lines WL and the select gate lines SGD and SGS constituting a terrace portion shift from an upper layer side to a lower layer side, and thus, the height position of the terrace portion decreases toward the source line SL.

It is noted that, in the present specification, a direction in which the terrace surfaces of the plurality of word lines WL and the select gate lines SGD and SGS face is defined as an upper side of the semiconductor memory device 1.

The separation layer SHE extends from the memory region MR to parts where the select gate line SGD of the staircase region SR is processed stepwise. As a result, in one block region BLK, the select gate line SGD is separated into a plurality of regions. In other words, the separation layer SHE penetrates upper layer parts above the plurality of word lines WL, so that the upper layer parts are partitioned into patterns of the plurality of select gate lines SGD.

A contact CC connected to the word line WL and the select gate lines SGD and SGS of each layer is disposed on a terrace portion of each step including the plurality of word lines WL and the select gate lines SGD and SGS. In the word line WL and the select gate line SGS, one contact CC is connected for each layer. In the select gate line SGD, one contact CC is connected, per layer, for each section obtained as a result of the separation with the separation layer SHE.

In one block region BLK, the plurality of contacts CC is disposed on the staircase regions SR on one of both sides in the X direction. When viewed on one side in the X direction, for example, a plurality of contacts CC is disposed every two of the block regions BLK.

That is, in the example of FIG. 1B, in the block region BLK at the uppermost part of the drawing, a plurality of contacts CC is disposed, for example, in the staircase region SR on the left side in the drawing among the staircase regions SR at both ends in the X direction. In each of the block regions BLK one below and two below the block region BLK mentioned above, a plurality of contacts CC is disposed in the staircase region SR on the right side in the drawing among the staircase regions SR at both ends in the X direction. Further, in the block region BLK at the lowermost part of the drawing, a plurality of contacts CC is disposed in the staircase region SR on the left side in the drawing.

Therefore, the contacts CC of the staircase regions SR at both ends in the X direction illustrated in FIG. 1A belong to different block regions BLK, and are not actually located in the same cross section.

The word lines WL and the like stacked in multiple layers are individually led out by the contacts CC. More specifically, from the contacts CC, a write voltage, a read voltage, and the like are applied to the memory cells included in the memory regions MR at the central portions of the plurality of word lines WL via the word line WL at the same height position as the memory cells.

The plurality of word lines WL, the select gate lines SGD and SGS, the pillars PL, and the contacts CC are covered with an insulating layer 50. The insulating layer 50 also extends around the configurations including the plurality of word lines WL.

The semiconductor substrate SB above the insulating layer 50 covering the configuration described above is, for example, a silicon substrate or the like. A peripheral circuit CBA including a transistor TR and wiring is disposed on the surface of the semiconductor substrate SB. The peripheral circuit CBA electrically connected to the contacts CC controls various voltages applied from the contacts CC to the memory cells. As a result, the peripheral circuit CBA controls the electrical operation of the memory cells.

The peripheral circuit CBA is covered with an insulating layer 40. The insulating layer 40 and the insulating layer 50 covering the plurality of word lines WL and the like are joined to form the semiconductor memory device 1 including the configuration of the plurality of word lines WL and the select gate lines SGD and SGS, the pillars PL, and the contacts CC, and the peripheral circuit CBA.

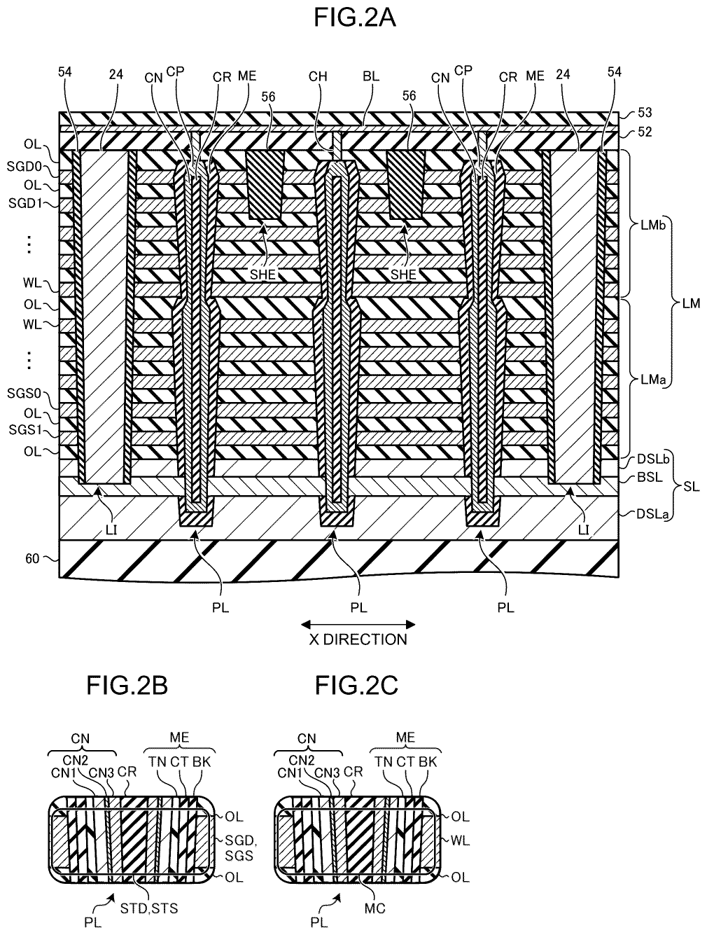

Next, a detailed configuration example of the semiconductor memory device 1 will be described with reference to FIGS. 2A to 2C. FIGS. 2A to 2C are cross-sectional views illustrating an example of a configuration of the semiconductor memory device 1 according to the embodiment.

More specifically, FIG. 2A is a cross-sectional view along the Y direction in the memory region MR of the semiconductor memory device 1. In FIG. 2A, structures below the insulating layer 60 and above an insulating layer 53, described later, are omitted.

FIG. 2B is an enlarged cross-sectional view of the pillar PL at the height positions of the select gate lines SGD and SGS. FIG. 2C is an enlarged cross-sectional view of the pillar PL at the height position of the word line WL.

As illustrated in FIG. 2A, the source line SL has a multilayer structure in which, for example, a lower source line DSLa, an intermediate source line BSL, and an upper source line DSLb are stacked in this order on the insulating layer 60. The lower source line DSLa, the intermediate source line BSL, and the upper source line DSLb are, for example, polysilicon layers. Among them, at least the intermediate source line BSL may be a conductive polysilicon layer or the like in which impurities are diffused.

The source line SL is connected via the electrode film EL to the peripheral circuit CBA via a through contact (not illustrated) extending from the electrode film EL in the insulating layer 50 outside a stacked body LM toward the peripheral circuit CBA.

The stacked body LM is disposed on the source line SL. The stacked body LM includes stacked bodies LMa and LMb in each of which a plurality of word lines WL and a plurality of insulating layers OL are alternately stacked one by one.

The stacked body LMa is disposed on the source line SL. A plurality of select gate lines SGS0 and SGS1 is disposed in this order from the upper layer side of the stacked body LMa via the insulating layer OL in a lower layer below the word line WL at the lowermost layer of the stacked body LMa. The stacked body LMb is disposed on the stacked body LMa. A plurality of select gate lines SGD0 and SGD1 is disposed in this order from the upper layer side of the stacked body LMb via the insulating layer OL in an upper layer above the word line WL at the uppermost layer of the stacked body LMb.

However, the number of word lines WL and select gate lines SGD and SGS stacked in the stacked body LM is freely selected. Each of the word lines WL and the select gate lines SGD and SGS is, for example, a tungsten layer or a molybdenum layer. The insulating layer OL is, for example, a silicon oxide layer or the like.

The upper surface of the stacked body LM is covered with the insulating layers 52 and 53 in this order. Each of the insulating layers 52 and 53 constitutes a part of the insulating layer 50 in FIG. 1A.

As described above, the stacked body LM is divided in the Y direction by the plurality of plate-like contacts LI. That is, the plate-like contacts LI are arranged in the Y direction and extend in the stacking direction of the stacked body LM and the direction along the X direction.

As described above, the plate-like contact LI continuously extends in the stacked body LM from one end to the other end of the stacked body LM in the X direction. The plate-like contact LI penetrates the stacked body LM and the upper source line DSLb to reach the intermediate source line BSL in the memory region MR.

In addition, the plate-like contact LI has, for example, a tapered shape in which the width in the Y direction decreases from the upper end toward the lower end. Alternatively, the plate-like contact LI has, for example, a bowing shape in which the width in the Y direction is maximized at a predetermined position between the upper end and the lower end.

Each of the plate-like contacts LI includes an insulating layer 54 and a conductive layer 24. The insulating layer 54 is, for example, a silicon oxide layer or the like. The conductive layer 24 is, for example, a tungsten layer or a conductive polysilicon layer.

The insulating layer 54 covers the side walls of the plate-like contact LI facing each other in the Y direction. The conductive layer 24 is filled further inside the insulating layer 54 covering the side walls of the plate-like contact LI, and is electrically connected to the source line SL including the intermediate source line BSL.

However, instead of the plate-like contact LI, a plate-like member filled with an insulating layer may penetrate the stacked body LM and extend in the direction along the X direction, thereby dividing the stacked body LM in the Y direction.

Between the plate-like contacts LI adjacent in the Y direction, a plurality of separation layers SHE extending through the upper layer part of the stacked body LMb in the direction along the X direction is disposed. The separation layers SHE are insulating layers 56 such as silicon oxide layers that penetrate the select gate lines SGD0 and SGD1 to reach the insulating layer OL immediately below the select gate line SGD1.

In other words, the separation layers SHE penetrating the upper layer part of the stacked body LMb extend over the memory region MR and a part of the staircase region SR in the X direction between the plate-like contacts LI, so that the upper layer part of the stacked body LMb is partitioned into the select gate lines SGD0 and SGD1 described above.

In the memory regions MR, a plurality of pillars PL penetrating the stacked body LM, the upper source line DSLb, and the intermediate source line BSL to reach the lower source line DSLa is dispersedly arranged.

The plurality of pillars PL are arranged, for example, in a staggered shape when viewed from the stacking direction of the stacked body LM. Each pillar PL has, as a cross-sectional shape in a direction along the layer direction of the stacked body LM, namely, in a direction along the XY plane, a circular shape, an elliptical shape, an ovoid shape (oval shape), or the like, for example.

In addition, each of the pillars PL has a tapered shape in which the diameter and the cross-sectional area decrease from the upper layer toward the lower layer at a part penetrating the stacked body LMa and at a part penetrating the stacked body LMb. Alternatively, each of the pillars PL has a bowing shape in which the diameter and the cross-sectional area are maximized at a predetermined position between the upper layer side and the lower layer side, for example, at a part penetrating the stacked body LMa and at a part penetrating the stacked body LMb.

Each of the pillars PL includes a memory layer ME extending in the stacked body LM in the stacking direction, a channel layer CN extending in the stacked body LM in the stacking direction inside the memory layer ME, a cap layer CP covering an upper surface of the channel layer CN, and a core layer CR serving as a core material of the pillar PL.

The channel layer CN is in direct contact with the intermediate source line BSL at the depth position of the intermediate source line BSL. That is, the memory layer ME is disposed on the side surface of the pillar PL except for the depth position of the intermediate source line BSL. The memory layer ME is also disposed on the bottom surface of the pillar PL reaching the depth of the lower source line DSLa.

This allows the channel layer CN to be in contact with the intermediate source line BSL at the side surface, and be further electrically connected to the entire source line SL via the intermediate source line BSL.

The cap layer CP is disposed at the upper end of the pillar PL so as to cover at least the upper end of the channel layer CN, and is connected to the channel layer CN. Further, the cap layer CP is connected to a bit line BL disposed in the insulating layer 53 via a plug CH disposed in the uppermost insulating layers OL and 52 of the stacked body LM. The bit line BL extends above the stacked body LM in the direction along the Y direction so as to intersect the drawing direction of the word lines WL.

As illustrated in FIGS. 2B and 2C, the memory layer ME has a stacked structure including a block insulating layer BK, a charge storage layer CT, and a tunnel insulating layer TN in this order from the outer peripheral side of the pillar PL. The block insulating layer BK and the tunnel insulating layer TN of the memory layer ME, and the core layer CR are, for example, silicon oxide layers or the like. The charge storage layer CT is, for example, a silicon nitride layer or the like.

The channel layer CN includes semiconductor layers CN1, CN2, and CN3 in order from the memory layer ME side.

The semiconductor layer CN1 is a semiconductor layer having high crystallinity, and is, for example, a single crystal silicon layer or the like. The semiconductor layer CN3 has, for example, more grain boundaries than the semiconductor layer CN1, and is, for example, a polycrystalline silicon layer, namely, a polysilicon layer or the like. However, the semiconductor layer CN3 may partially include an amorphous semiconductor layer, namely, an amorphous silicon layer.

The semiconductor layer CN2 is, for example, a semiconductor layer such as a silicon layer containing an additive of at least one of carbon, nitrogen, oxygen, and fluorine. The concentration of the additive in the semiconductor layer CN2 is preferably, for example, greater than 2×10²¹ atoms/cm³. The additive in the semiconductor layer CN2 is partially diffused into at least one of the semiconductor layers CN1 and CN3, so that at least one of the semiconductor layers CN1 and CN3 may contain an additive at a concentration lower than that of the semiconductor layer CN2.

With such a configuration, the channel layer CN as a whole contains an additive having a peak concentration at the interface between the semiconductor layer CN1 and the semiconductor layer CN3.

Similarly to the semiconductor layer CN3, the cap layer CP is a semiconductor layer such as polysilicon or polysilicon in which amorphous silicon is mixed. The cap layer CP may contain N-type impurities such as arsenic or phosphorus. The cap layer CP is, for example, a polycrystalline layer, and thus impurities are easily diffused thereinto as compared with a single crystal layer. Since the N-type impurities are diffused into the cap layer CP, contact resistance between the cap layer CP and the plug CH can be reduced.

With the configuration described above, as illustrated in FIG. 2C, the memory cells MC are formed in parts of the side surfaces of the pillars PL facing the word lines WL. When a predetermined voltage is applied from the word line WL, data is written to and read from the memory cell MC.

As illustrated in FIG. 2B, the select gates STD are formed in parts where the side surfaces of the pillars PL face the select gate lines SGD0 and SGD1. In addition, the select gates STS are formed in parts where the side surfaces of the pillars PL face the select gate lines SGS0 and SGS1 below the word lines WL.

When predetermined voltages are applied from the select gate lines SGD and SGS, the select gates STD and STS are turned on or off, and the memory cells MC of the pillar PL to which the select gates STD and STS belong can be set to a selected state or a non-selected state.

### Method for Manufacturing Semiconductor Memory Device

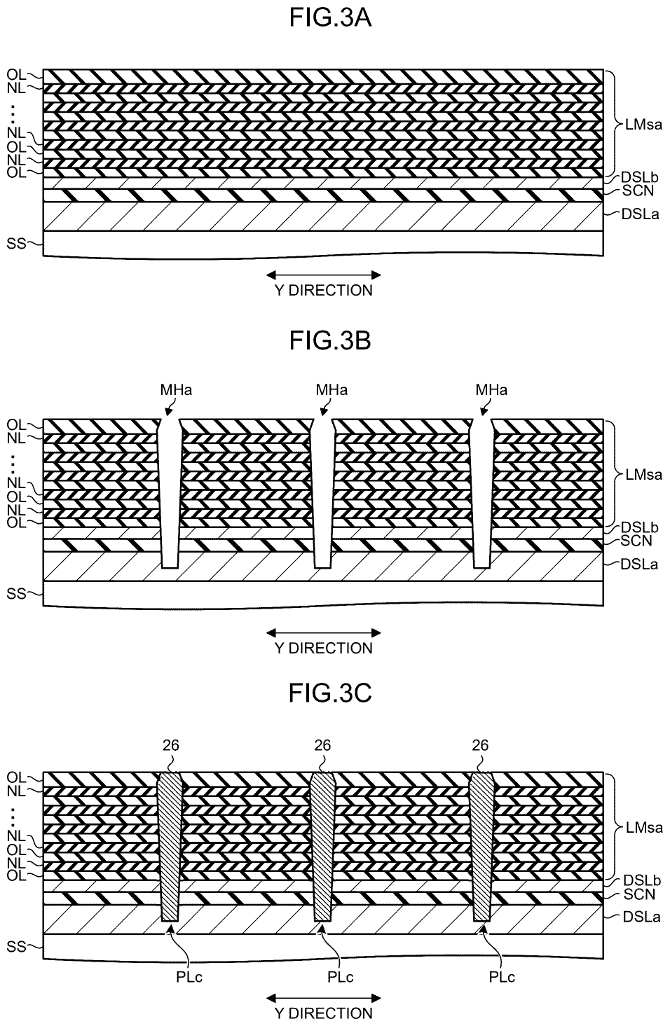

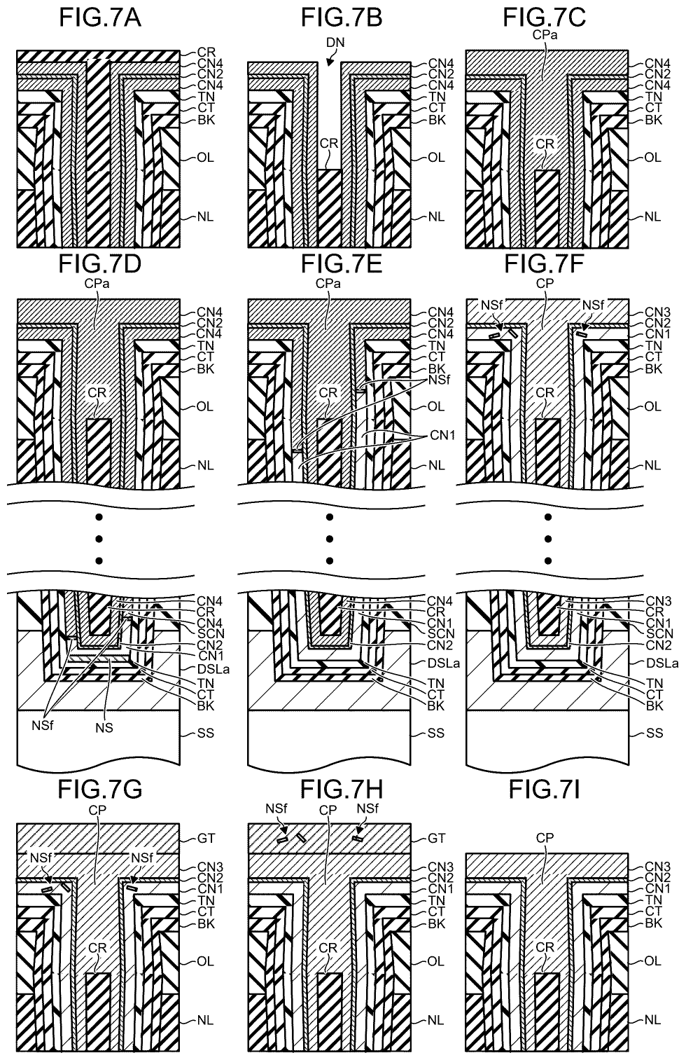

Next, a method for manufacturing the semiconductor memory device 1 according to the embodiment will be described with reference to FIGS. 3A to 12B. FIGS. 3A to 12B are diagrams sequentially illustrating some procedures of a method for manufacturing the semiconductor memory device 1 according to the embodiment. It is noted that FIGS. 3A to 12B excluding FIGS. 7A to 7I each illustrate a cross section along the Y direction of a region where the memory region MR is to be formed later. FIGS. 7A to 7I are partially enlarged cross-sectional views of the pillar PL in the middle of manufacturing.

As illustrated in FIG. 3A, the lower source line DSLa, an intermediate sacrificial layer SCN, and the upper source line DSLb are formed in this order on a support substrate SS.

As the support substrate SS, a semiconductor substrate such as a silicon substrate, an insulating substrate such as a ceramic substrate, a conductive substrate, or the like can be used. The insulating layer 60 (see FIG. 2A and the like) may be formed on the upper surface side of the support substrate SS. The intermediate sacrificial layer SCN is, for example, a silicon nitride layer or the like, and is a layer to be replaced with a polysilicon layer or the like later to become the intermediate source line BSL.

A stacked body LMsa in which a plurality of insulating layers NL and a plurality of insulating layers OL are alternately stacked one by one is formed on the upper source line DSLb. The insulating layer NL is, for example, a silicon nitride layer or the like, and is a layer to be replaced with a conductive material later and functions as a sacrificial layer that is to become the word line WL or the select gate line SGS.

Thereafter, although not illustrated, the insulating layers NL and the insulating layers OL are processed stepwise in a partial region of the stacked body LMsa. Such processing can be performed by repeating, a plurality of times, slimming of a mask pattern such as a photoresist layer and etching of the insulating layers NL and the insulating layers OL of the stacked body LMsa.

That is, a mask pattern is formed on the upper surface of the stacked body LMsa, and the insulating layer NL and the insulating layer OL at an exposed part are etched away one by one. In addition, by processing using oxygen plasma for example, an end of the mask pattern is retracted to newly expose the upper surface of the stacked body LMsa, and then the insulating layer NL and the insulating layer OL are further etched away one by one. Such processing is repeated a plurality of times to form the stacked body LMsa having a staircase shape at both ends in the X direction.

Thereafter, the staircase shape at both ends in the X direction is covered with a part of the insulating layer 50 (see FIG. 1A).

As illustrated in FIG. 3B, a plurality of memory holes MHa extending in the stacking direction of the stacked body LMsa is formed. The plurality of memory holes MHa penetrates the stacked body LMsa, the upper source line DSLb, and the intermediate sacrificial layer SCN to reach the lower source line DSLa. The memory holes MHa are parts that are to become lower structures of the pillars PL later.

As illustrated in FIG. 3C, the memory holes MHa are filled with sacrificial layers 26 such as amorphous silicon layers or CVD-carbon layers. As a result, pillars PLc in which the plurality of memory holes MHa is filled with the sacrificial layers 26 are formed.

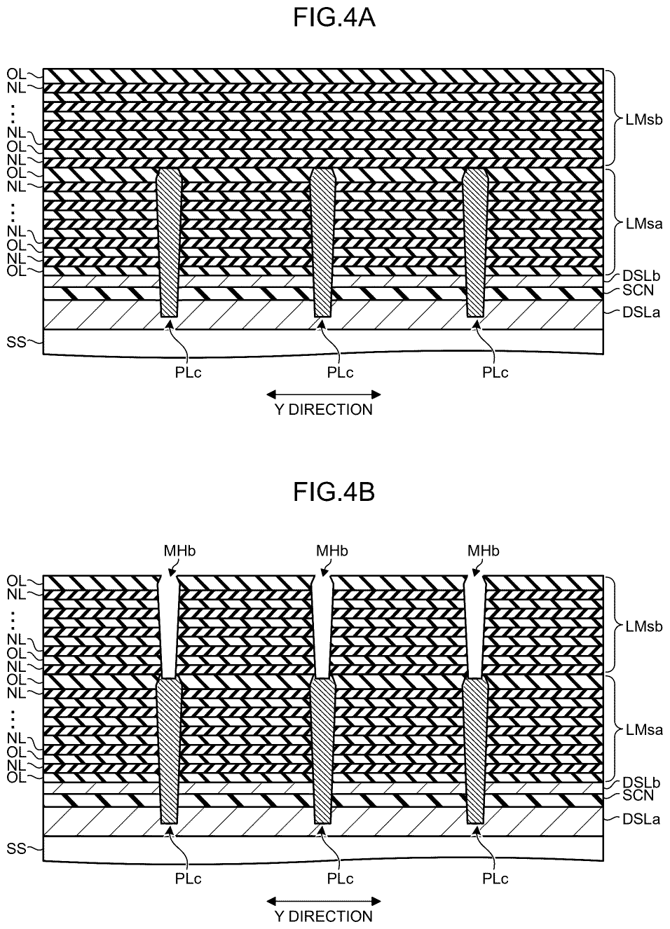

As illustrated in FIG. 4A, a stacked body LMsb is formed which covers the stacked body LMsa and has a plurality of insulating layers NL and a plurality of insulating layers OL alternately stacked one by one. The insulating layer NL of the stacked body LMsb is a layer to be replaced with a conductive layer later and functions as a sacrificial layer that is to become the word line WL or the select gate line SGD.

Thereafter, although not illustrated, the insulating layers NL and the insulating layers OL are processed stepwise in a partial region of the stacked body LMsb. Similarly to the process on the stacked body LMsa, such processing can be performed by repeating, a plurality of times, slimming of a mask pattern such as a photoresist layer and etching of the insulating layers NL and the insulating layers OL of the stacked body LMsb.

At this time, the uppermost step of the staircase portion formed in the stacked body LMsa and the lowermost step of the staircase portion formed in the stacked body LMsb are brought close to each other to form a staircase shape that continuously connects from the lower layer side of the stacked body LMsa to the upper layer side of the stacked body LMsb. As a result, the stacked bodies LMsa and LMsb are formed in which the staircase region SR having a staircase shape is formed at each end in the X direction from the stacked body LMsa to the stacked body LMsb.

Thereafter, the staircase shape at both ends in the X direction is further covered with a part of the insulating layer 50 (see FIG. 1A).

As illustrated in FIG. 4B, a plurality of memory holes MHb penetrating the stacked body LMsb and connected to the plurality of pillars PLc formed in the stacked body LMsa is formed. The memory holes MHb are parts that are to become upper structures of the pillars PL later.

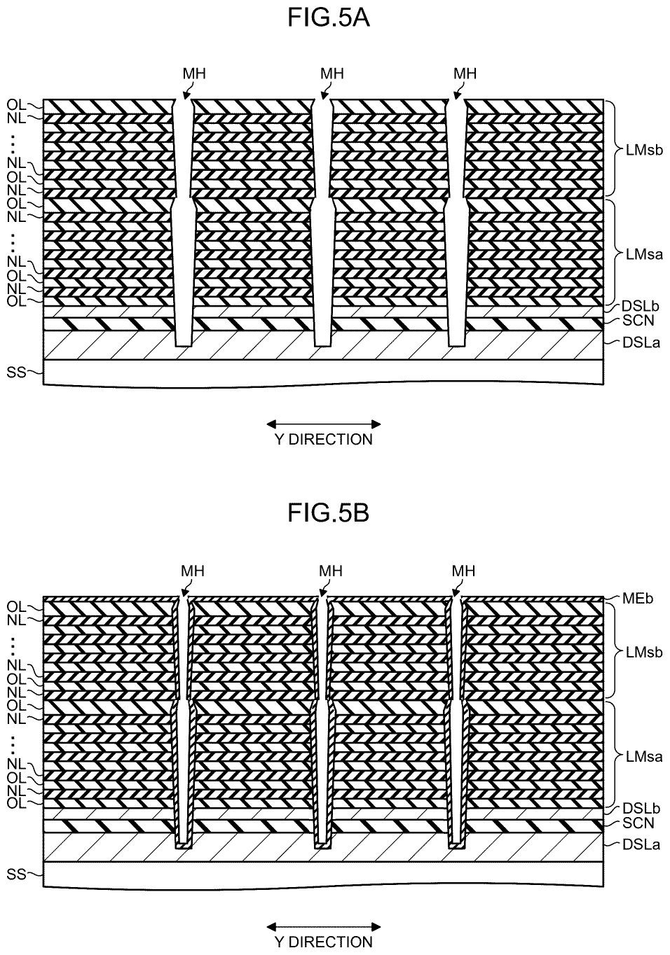

As illustrated in FIG. 5A, the sacrificial layer 26 is removed from the pillar PLc at the bottom of the memory hole MHb. As a result, the memory holes MHa are open at the bottoms of the plurality of memory holes MHb, and a plurality of memory holes MH each penetrating the stacked bodies LMsb and LMsa, the upper source line DSLb, and the intermediate sacrificial layer SCN to reach the lower source line DSLa is formed.

In a case where the sacrificial layers 26 filled in the pillars PLc are CVD-carbon layers or the like, the sacrificial layers 26 can be collectively removed from the pillars PLc when the mask pattern or the like used at the formation of the memory holes MHb in FIG. 4B described above is removed by ashing or the like using oxygen plasma.

As illustrated in FIG. 5B, the memory layer ME including the block insulating layer BK, the charge storage layer CT, and the tunnel insulating layer TN (see FIGS. 2B and 2C) in this order from the side wall of the memory hole MH is formed on the side walls of the memory hole MH and the bottom surface at which the lower source line DSLa is exposed. The memory layer ME is formed also on the upper surface of the stacked body LMsb.

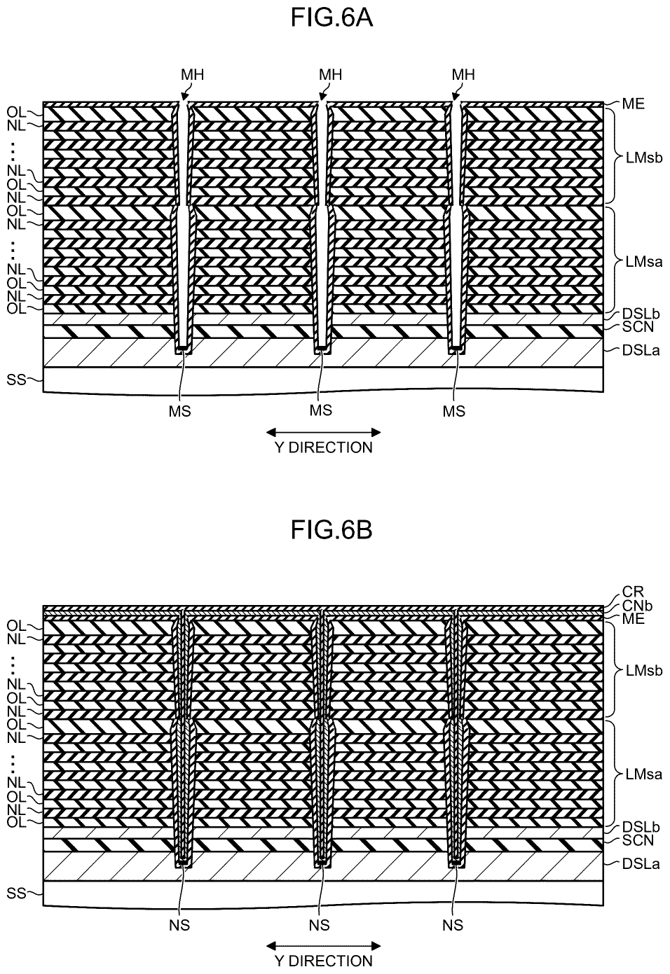

As illustrated in FIG. 6A, a metal layer MS is formed on the memory layer ME covering the bottom surface of the memory hole MH. The metal layer MS is a layer containing, for example, at least one of nickel, palladium, and aluminum.

As illustrated in FIG. 6B, a channel layer CNb and the core layer CR are formed in the memory hole MH in this order. As a result, the channel layer CNb is formed on the memory layer ME covering the side surfaces and the bottom surface of the memory hole MH and the metal layer MS, and the core layer CR is filled in the central portion of the memory hole MH. The channel layer CNb and the core layer CR are formed in this order also on the upper surface of the stacked body LMsb via the memory layer ME.

The channel layer CNb is a semiconductor layer that is to become the channel layer CN later. At this point in time, the entire channel layer CNb is an amorphous semiconductor layer such as an amorphous silicon layer.

In the above, the channel layer CNb is formed so as to have a peak concentration at a predetermined position in the channel layer CNb by adding at least one of carbon, nitrogen, oxygen, and fluorine in midstream.

As illustrated in FIG. 7A, the channel layer CNb has a structure in which the semiconductor layer CN2 is interposed in a semiconductor layer CN4 that results in the semiconductor layers CN1 and CN3 by the addition of carbon, nitrogen, oxygen, fluorine, and the like. The channel layer CNb covering the metal layer MS on the memory layer MEb is formed to thereby silicide the metal layer MS.

As illustrated in FIG. 7B, the core layer CR formed on the upper surface of the stacked body LMsb is etched back and removed, and the core layer CR in the memory hole MH is retracted to form a recess DN at the upper end of the memory hole MH.

As illustrated in FIG. 7C, a cap layer CPa is formed in the recess DN at the upper end of the memory hole MH. The cap layer CPa is, for example, an amorphous semiconductor layer such as an amorphous silicon layer, and is a layer that is to become the cap layer CP later. The cap layer CPa is formed also on the upper surface of the stacked body LMsb via the memory layer ME and the semiconductor layers CN4, CN2, and CN4.

When the cap layer CPa is formed, the N-type impurities such as arsenic or phosphorus may be added to the cap layer CPa as described above.

As illustrated in FIG. 7D, the entire support substrate SS is annealed at a low temperature. The annealing process at a low temperature is, for example, a heat treatment at a temperature at which crystallization of the semiconductor layer CN4 does not occur. However, a metal-containing layer NS that is provided at the lower end of the memory hole MH and obtained by silicidation of the metal layer MS has a function of promoting crystallization of the semiconductor layer CN4. That is, the metal-containing layer NS functions as a catalyst for crystallization of the semiconductor layer CN4.

Therefore, the annealing process starts crystallization of the semiconductor layer CN4 that is located closer to the memory layer ME than the semiconductor layer CN2 and is in direct contact with the metal-containing layer NS. The process of crystallizing the semiconductor layer CN4 by the annealing process using the metal-containing layer NS or the like as described above is also referred to as metal-assisted annealing process.

A part of the metal-containing layer NS serving as a catalyst for crystallization of the semiconductor layer CN4 is diffused into the semiconductor layer CN4 as metal fragments NSf, each of which is shredded from the metal-containing layer NS. A part of the semiconductor layer CN4 where the metal fragments NSf have entered is changed to the above-described semiconductor layer CN1 which is, for example, a single crystal silicon layer.

On the other hand, the semiconductor layer CN2 containing a high concentration of an additive of at least one of carbon, nitrogen, oxygen, and fluorine, for example has a function of inhibiting the progress of crystallization of the semiconductor layer CN4 in the metal-assisted annealing process. Accordingly, the crystallization started in the semiconductor layer CN4 closer to the memory layer ME at the lower end of the memory hole MH does not progress in the semiconductor layer CN4 closer to the core layer CR inside the semiconductor layer CN4.

As illustrated in FIG. 7E, the crystallization that has started in the semiconductor layer CN4 at the lower end of the memory hole MH further progresses upward in the semiconductor layer CN4 outside the semiconductor layer CN2. In addition, since the metal-containing layer NS formed on the bottom surface of the memory hole MH is diffused into the semiconductor layer CN4 as the metal fragment NSf as described above, the metal-containing layer NS disappears at a predetermined stage of the metal-assisted annealing process.

As illustrated in FIG. 7F, when the crystallization progresses up to the upper end of the memory hole MH, the entire semiconductor layer CN4 outside the semiconductor layer CN2 becomes the semiconductor layer CN1 such as a single crystal silicon layer. The metal fragment NSf that has entered the semiconductor layer CN4 up to the upper end thereof is segregated at the upper end of the crystallized semiconductor layer CN1.

On the other hand, the semiconductor layer CN4 inside the semiconductor layer CN2 is not subjected to the action of metal-assisted crystallization because the semiconductor layer CN4 is blocked by the semiconductor layer CN2. However, by the annealing process at a low temperature, the entirety of the semiconductor layer CN4 changes to the semiconductor layer CN3 such as a polysilicon layer at the end of the annealing process. As described above, the amorphous silicon layer may be mixed in a part of the semiconductor layer CN3.

In the manufacturing process of the semiconductor memory device 1 of the embodiment, annealing process for various layers and the like to be formed later can be repeatedly performed. Accordingly, in the semiconductor layer CN3, polycrystallization may gradually progress not only by the metal-assisted annealing process at the time of forming the semiconductor layer CN1 but also by the annealing process performed thereafter.

Similarly, the entire cap layer CPa at the upper end of the memory hole MH is also changed to a polysilicon layer, a polysilicon layer in which an amorphous silicon layer is partially mixed, or the like through the annealing process. In a case where the N-type impurities are contained in the cap layer CPa, the N-type impurities are more uniformly diffused into the polycrystalline cap layer CP by the annealing process, and the N-type impurities are activated.

The additive in the semiconductor layer CN2 may be partially diffused into the semiconductor layers CN1, CN3, and so on by the annealing process or the like.

In this way, the channel layer CN including the semiconductor layers CN1, CN2, and CN3 is formed. The cap layer CP is formed at the upper end of the channel layer CN.

As illustrated in FIG. 7G, a gettering layer GT such as an amorphous silicon layer is formed on the upper surface of the channel layer CN.

As illustrated in FIG. 7H, by performing the annealing process, the metal fragment NSf segregated in the upper end of the channel layer CN moves into the gettering layer GT. As a result, most of the metal fragment NSf in the channel layer CN can be removed.

As illustrated in FIG. 7I, the gettering layer GT is then removed.

In this manner, the channel layer CN is formed in which the semiconductor layer CN2 to which the additive has been added is interposed between the semiconductor layer CN1 having few grain boundaries and the semiconductor layer CN3 having many grain boundaries.

In the metal-assisted annealing process, the crystallization is more easily promoted as the layer to be crystallized is thicker. Accordingly, the channel layer CNb may be formed to be thicker than the channel layer CN to be finally included in the pillar PL, then to perform crystallization.

In a case where the channel layer CNb is formed to be thick, after a part of the channel layer CNb is crystallized, the core layer CR is temporarily removed to slim the channel layer CN exposed in the memory hole MH, so that a desired layer thickness can be obtained. Thereafter, the core layer CR is formed again in the memory hole MH.

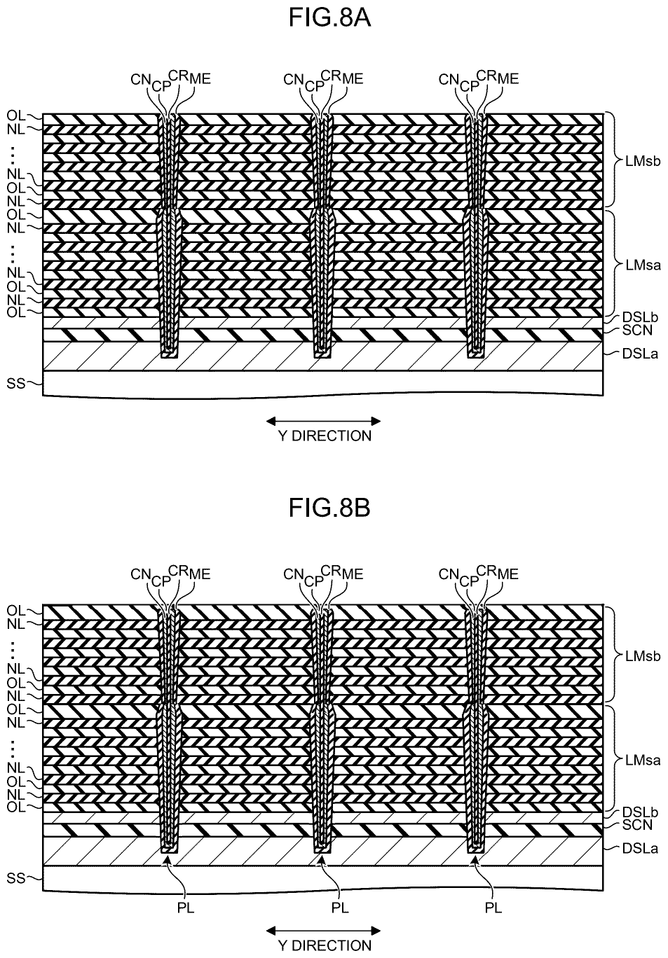

As illustrated in FIG. 8A, the cap layer CP, the channel layer CN, and the memory layer ME on the upper surface of the stacked body LMsb are removed together with a part of the insulating layer OL that is the uppermost layer of the stacked body LMsb by CMP or the like.

As illustrated in FIG. 8B, the insulating layer OL that is the uppermost layer of the stacked body LMsb thinned by CMP or the like is further stacked. As a result, the pillar PL in which the cap layer CP is buried in the uppermost insulating layer OL is formed. However, at this point in time, the memory layer ME covers the entire side wall of the pillar PL, and a part of the side surface of the channel layer CN is not exposed from the memory layer ME.

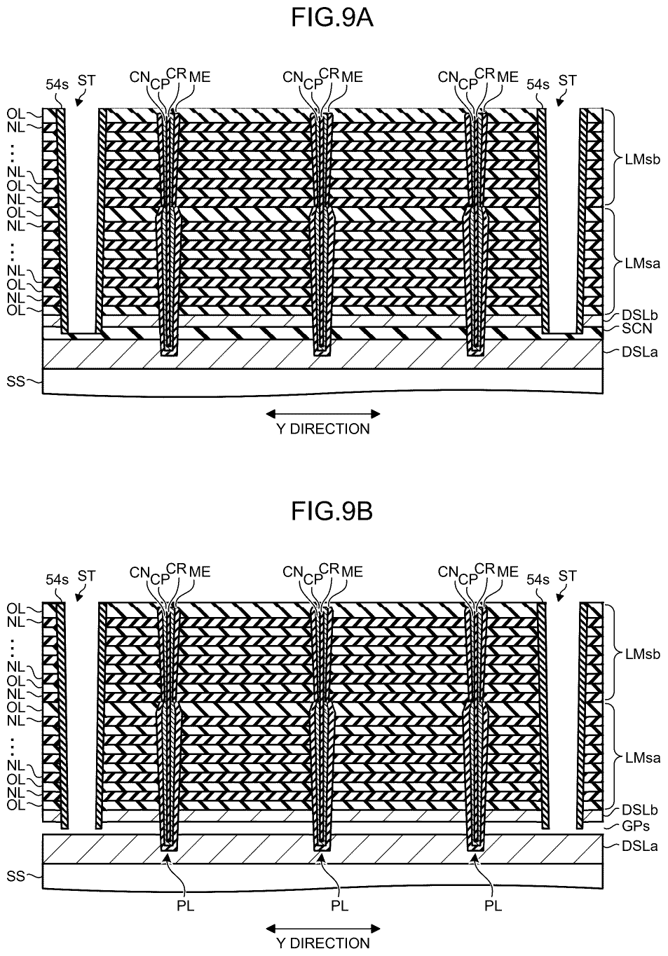

As illustrated in FIG. 9A, a slit ST that penetrates the stacked bodies LMsb and LMsa and the upper source line DSLb to reach the intermediate sacrificial layer SCN is formed. Further, insulating layers 54s are formed on the side walls of the slit ST facing each other in the Y direction. The slit ST also extends in the direction along the X direction in the stacked bodies LMsa and LMsb.

As illustrated in FIG. 9B, a removing liquid for the intermediate sacrificial layer SCN such as thermal phosphoric acid is caused to flow through the slit ST whose side walls are protected by the insulating layers 54s, and the intermediate sacrificial layer SCN sandwiched between the lower source line DSLa and the upper source line DSLb is removed.

This forms a gap layer GPs between the lower source line DSLa and the upper source line DSLb. Further, a part of the memory layer ME in the outer peripheral portion of the pillar PL is exposed in the gap layer GPs. At this time, since the side walls of the slit ST are protected by the insulating layers 54s, removal of the insulating layers NL in the stacked bodies LMsa and LMsb is prevented.

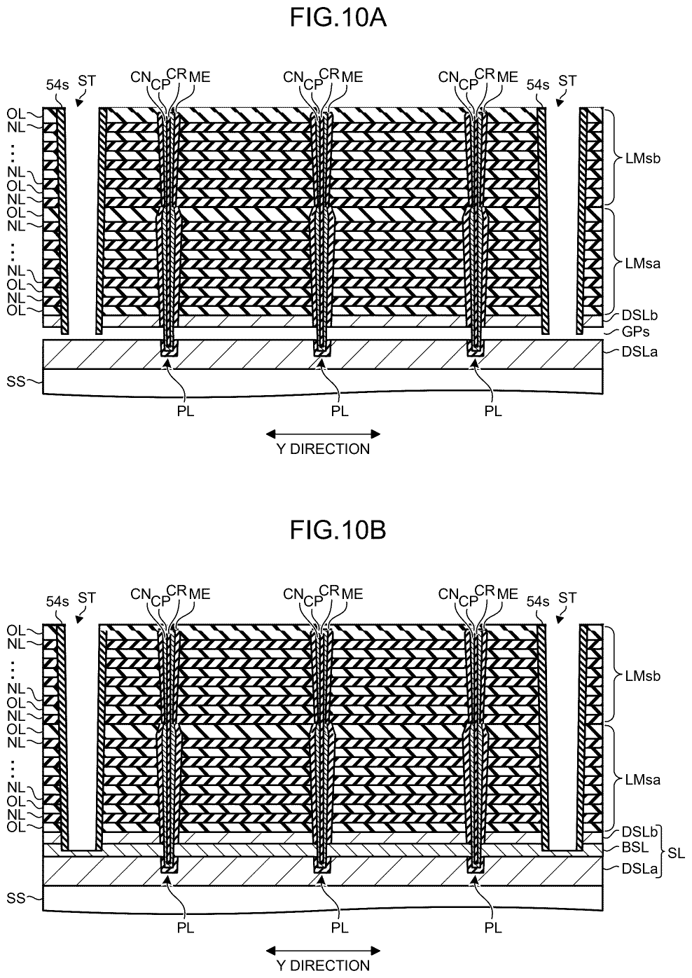

As illustrated in FIG. 10A, a chemical liquid is caused to flow appropriately into the gap layer GPs through the slit ST, and the block insulating layer BK, the charge storage layer CT, and the tunnel insulating layer TN (see FIGS. 2B and 2C) of the memory layer ME exposed in the gap layer GPs are sequentially removed. As a result, the memory layer ME is removed from a part of the side walls of the pillar PL, and a part of the channel layer CN on the inner side is exposed in the gap layer GPs.

As illustrated in FIG. 10B, a source gas of amorphous silicon or the like is injected from the slit ST whose side walls are protected by the insulating layers 54s, and the gap layer GPs is filled with amorphous silicon or the like. Further, the support substrate SS is heat-treated to polycrystallize the amorphous silicon filled in the gap layer GPs, thereby forming the intermediate source line BSL containing polysilicon or the like.

Thereby, a part of the channel layer CN of the pillar PL is connected to the source line SL on the side surface via the intermediate source line BSL.

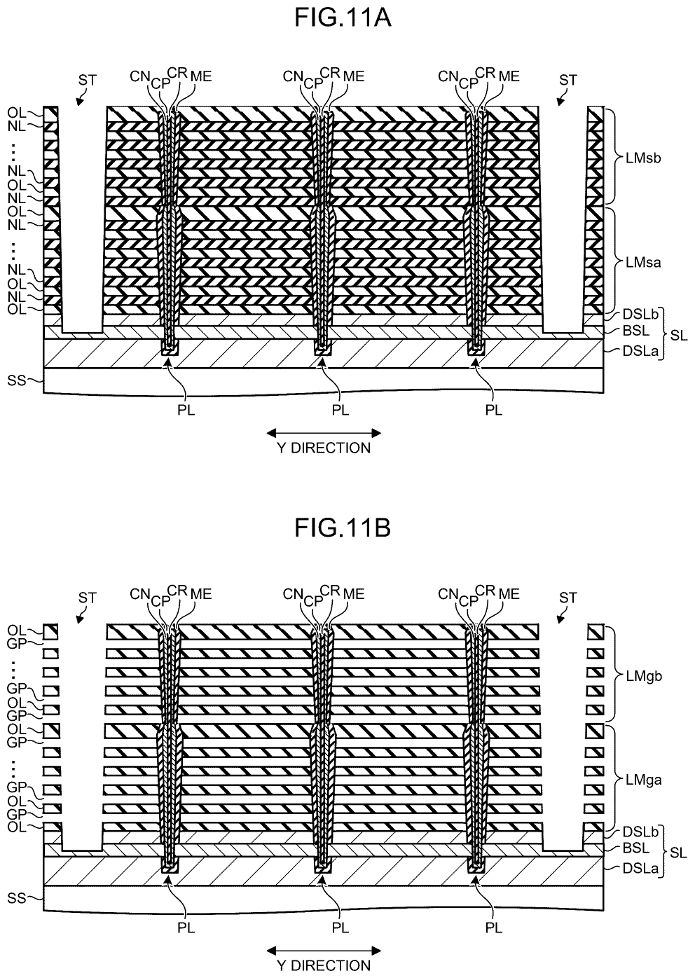

As illustrated in FIG. 11 A, the insulating layers 54s on the side walls of the slit ST are removed.

As illustrated in FIG. 11B, a removing liquid for the insulating layer NL such as thermal phosphoric acid is caused to flow from the slit ST from which the insulating layers 54s have been removed into the stacked bodies LMsa and LMsb to thereby remove the insulating layers NL of the stacked bodies LMsa and LMsb. As a result, stacked bodies LMga and LMgb having a plurality of gap layers GP obtained by removing the insulating layers NL between the insulating layers OL are formed.

The stacked bodies LMga and LMgb including the plurality of gap layers GP have a fragile structure. The plurality of pillars PL supports such fragile stacked bodies LMga and LMgb. This prevents the insulating layers OL remaining in the stacked bodies LMga and LMgb from deforming and prevents the stacked bodies LMga and LMgb from being distorted or collapsed.

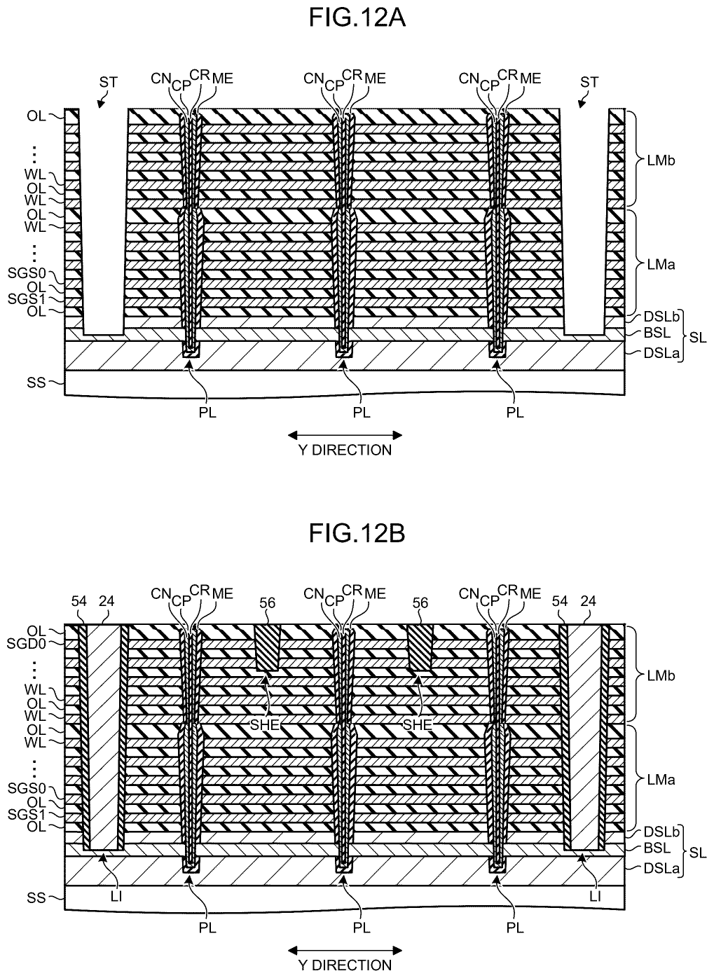

As illustrated in FIG. 12A, a source gas for a conductive material such as tungsten or molybdenum is injected from the slit ST into the stacked bodies LMga and LMgb, and the gap layers GP of the stacked bodies LMga and LMgb are filled with the conductive material to form the plurality of word lines WL and the like. As a result, the stacked body LM including the stacked bodies LMa and LMb in each of which the plurality of word lines WL and the like and the plurality of insulating layers OL are alternately stacked one by one is formed.

As described above, the process of forming the intermediate source line BSL from the intermediate sacrificial layer SCN and the process of forming the word line WL from the insulating layer NL are also referred to as replacement process.

As illustrated in FIG. 12B, the conductive layer 24 is filled in the slit ST via the insulating layer 54 to form the plate-like contact LI. In addition, a groove penetrating one or a plurality of conductive layers including the uppermost conductive layer of the stacked body LMb is formed, and the insulating layer 56 is filled in the groove, thereby forming the separation layer SHE that partitions the conductive layers into the pattern of the select gate line SGD.

Thereafter, although not illustrated, a plurality of contacts CC reaching the word lines WL and the select gate lines SGD and SGS constituting the steps of the staircase structure in the staircase region SR are formed from the upper side of the staircase region SR.

In addition, after the insulating layer 52 covering the stacked body LM is formed, a plug CH that penetrates the uppermost insulating layer OL and the insulating layer 52 of the stacked body LM and is connected to the cap layer CP at the upper end of the pillar PL is formed. Further, the insulating layer 53 covering the insulating layer 52 is formed, and the bit line BL to which each plug CH is connected is formed in the insulating layer 53.

For example, the plug CH, the bit line BL, and the like may be collectively formed by using a dual-damascene method or the like.

In addition, the peripheral circuit CBA is formed on the semiconductor substrate SB separate from the support substrate SS on which the stacked body LM is formed, and is covered with the insulating layer 40. In the insulating layer 40, a contact, a via, a wiring, or the like that leads out the peripheral circuit CBA to the surface of the insulating layer 40 is formed and connected to an electrode pad or the like formed on the upper surface of the insulating layer 40.

Subsequently, the support substrate SS and the semiconductor substrate SB are bonded to each other at the insulating layers 50 and 40, respectively, and the electrode pads in the insulating layers 50 and 40 are connected. Thereafter, the support substrate SS is removed to expose the source line SL, and the electrode film EL is connected via the insulating layer 60 on which the plug PG is formed.

As described above, the semiconductor memory device 1 according to the embodiment is manufactured.

### Overview

In a semiconductor memory device such as a three-dimensional nonvolatile memory, a technology is known for single-crystallizing a channel layer of a pillar. The technology improves carrier mobility in the channel layer and reduces noise because trapping due to grain boundaries does not occur. Meanwhile, impurities such as arsenic are hardly diffused into the single-crystal channel layer, and the threshold of the memory cells decreases as compared with the polycrystalline channel layer. In addition, in a case where single crystallization of the channel layer is incomplete and a part of the channel layer contains polycrystals, reliability of a memory cell located in a region where the polycrystals are mixed may be reduced.

According to the semiconductor memory device 1 of the embodiment, the pillar PL includes the semiconductor layer CN1 extending in the stacked body LM in the stacking direction of the stacked body LM, and the semiconductor layer CN3 extending in the stacked body LM in the stacking direction of the stacked body LM and including grain boundaries more than grain boundaries of the semiconductor layer CN1, and includes an additive having a peak concentration at the interface between the semiconductor layer CN1 and the semiconductor layer CN3.

As described above, by forming the pillar PL with a two-layer structure of the semiconductor layer CN1 having few grain boundaries and the semiconductor layer CN3 having many grain boundaries, it is possible to achieve both improvement in carrier mobility as well as reduction in noise in the channel layer and construction of the memory cell MC in which threshold adjustment is easy. As a result, the operation characteristics of the memory cells MC such as write characteristics and read characteristics can be improved.

In addition, by using a structure containing an additive having a peak concentration at the interface between the semiconductor layer CN1 and the semiconductor layer CN3, when a part of the channel layer CNb (see FIGS. 7A to 7I and the like) is crystallized to form the semiconductor layer CN1, the progress of crystallization also in the semiconductor layer CN3 can be prevented.

According to the semiconductor memory device 1 of the embodiment, the cap layer CP contains N-type impurities. This reduces the contact resistance between the cap layer CP and the plug CH. In addition, since the cap layer CP is, for example, a polycrystalline layer or the like, the impurities can be easily diffused. Even in a case where the impurities are diffused into the channel layer CN, the impurities can be easily diffused into the channel layer CN at least through the semiconductor layer CN3 including the polysilicon layer because the channel layer CN includes the semiconductor layer CN1 and the semiconductor layer CN3.

According to the semiconductor memory device 1 of the embodiment, the peak concentration of the additive is greater than 2×10²¹ atoms/cm³. As a result, the semiconductor layer CN2 having the peak concentration of the additive in the channel layer CN can sufficiently function as a barrier that inhibits crystallization of a part of the channel layer CNb.

According to the semiconductor memory device 1 of the embodiment, the additive is at least one of carbon, nitrogen, oxygen, and fluorine. These elements are contained as the additives, which allows the semiconductor layer CN2 to sufficiently function as a barrier that inhibits crystallization of a part of the channel layer CNb.

According to the semiconductor memory device 1 of the embodiment, the semiconductor layer CN1 is a single crystal layer, and the semiconductor layer CN3 is a polycrystalline layer. As a result, the write characteristics of the memory cells MC can be further improved. In addition, since the pillar PL has a two-layer structure of the semiconductor layer CN1 and the semiconductor layer CN3, the threshold of the memory cell MC can be easily adjusted even when polycrystals are mixed in the semiconductor layer CN1 as compared with the case where the entire channel layer CNb is crystallized.

Therefore, the reliability of each memory cell MC can be further improved.

### Modification

In the embodiment described above, in the channel layer CN of the pillar PL, the semiconductor layer CN1 having few grain boundaries is disposed on the memory layer ME side, and the semiconductor layer CN3 having many grain boundaries is disposed on the core layer CR side via the semiconductor layer CN2 to which the additive has been added. However, the semiconductor layers CN1 and CN3 may be arranged in reverse order.

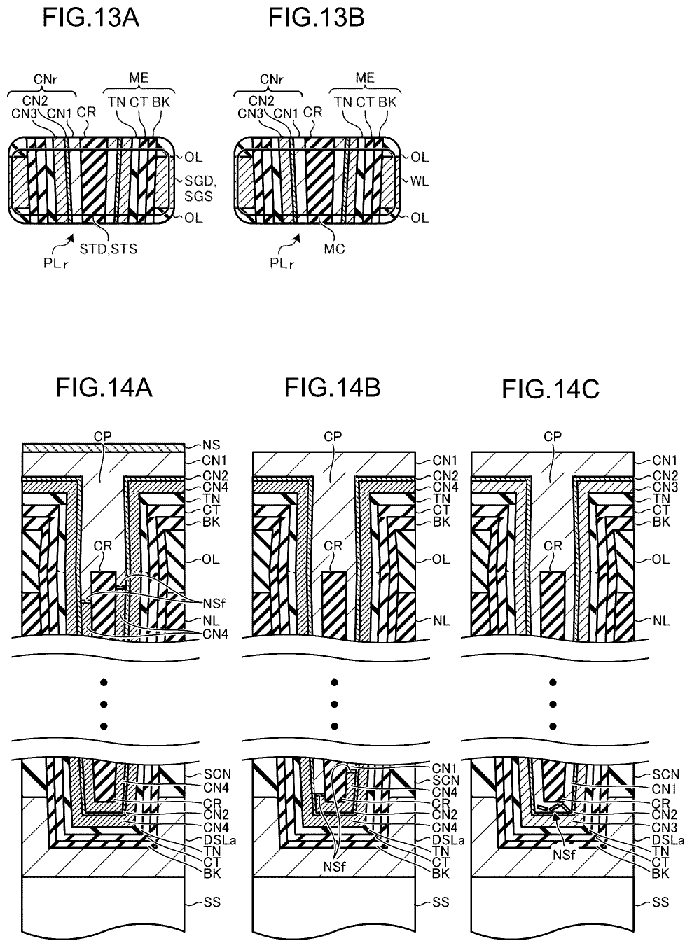

Hereinafter, a semiconductor memory device according to a modification to the embodiment will be described with reference to FIGS. 13A to 14C. In the semiconductor memory device of the modification, the arrangement of the semiconductor layers CN1 and CN3 in the channel layer CNr is different from that of the embodiment described above.

In the following drawings, the same reference numerals are given to the same configurations as those of the above-described embodiment, and the description thereof may be omitted.

FIGS. 13A and 13B are partially enlarged cross-sectional views of a pillar PLr included in the semiconductor memory device according to the modification to the embodiment. As illustrated in FIGS. 13A and 13B, the semiconductor memory device of the modification includes the pillar PLr having a channel layer CNr.

The channel layer CNr includes the semiconductor layers CN1, CN2, and CN3 similarly to the channel layer CN of the embodiment described above. However, in the channel layer CNr, the semiconductor layer CN1 is disposed on the core layer CR side, and the semiconductor layer CN3 is disposed on the memory layer ME side with the semiconductor layer CN2 interposed therebetween. The channel layer CNr can be formed, for example, as illustrated in FIGS. 14A to 14C as described below.

FIGS. 14A to 14C are diagrams illustrating some procedures of the method for manufacturing the semiconductor memory device according to the modification to the embodiment. More specifically, FIGS. 14A to 14C correspond to FIGS. 7A to 7I of the embodiment described above, and illustrate a state in which the channel layer CNr of the pillar PLr included in the semiconductor memory device of the modification is formed in a partially enlarged cross-sectional view of the pillar PLr in the middle of formation.

Also in a method for manufacturing the semiconductor memory device of the modification, the memory layer ME, the semiconductor layer CN4, the semiconductor layer CN2, the semiconductor layer CN4, and the core layer CR are formed in the pillar PLr in the middle of formation in order from the outer peripheral side of the pillar PLr, and the cap layer CPa is formed at the upper end of the pillar PLr.

As illustrated in FIG. 14A, the metal-containing layer NS is formed at the upper end of the pillar PLr in the middle of formation, and the entire support substrate SS is annealed at a low temperature.

As a result, metal-assisted crystallization is started in the cap layer CPa in direct contact with the metal-containing layer NS and the semiconductor layer CN4 covered with the cap layer CPa inside the semiconductor layer CN2. A part of the metal-containing layer NS serving as a catalyst for crystallization of the semiconductor layer CN4 is diffused into the semiconductor layer CN4 as metal fragments NSf, each of which is shredded from the metal-containing layer NS.

At this time, the semiconductor layer CN4 outside the semiconductor layer CN2 is shielded from the metal-containing layer NS by the semiconductor layer CN2, and is not subjected to the action of crystallization.

As illustrated in FIG. 14B, the crystallization started in the cap layer CPa at the upper end of the pillar PLr in the middle of formation further progresses downward in the semiconductor layer CN4 inside the semiconductor layer CN2. In addition, since the metal-containing layer NS formed on the upper end of the pillar PLr in the middle of formation is diffused into the semiconductor layer CN4 as the metal fragment NSf as described above, the metal-containing layer NS disappears at a predetermined stage of the metal-assisted annealing process.

As illustrated in FIG. 14C, when the crystallization progresses up to the lower end of the pillar PLr in the middle of formation, the entire semiconductor layer CN4 inside the semiconductor layer CN2 becomes the semiconductor layer CN1 such as a single crystal silicon layer. The metal fragment NSf that has entered the semiconductor layer CN4 up to the lower end thereof is segregated at the lower end of the crystallized semiconductor layer CN1.

On the other hand, the semiconductor layer CN4 outside the semiconductor layer CN2 is not subjected to the action of metal-assisted crystallization because the semiconductor layer CN4 is blocked by the semiconductor layer CN2. However, by the annealing process at a low temperature, the entirety of the semiconductor layer CN4 changes to the semiconductor layer CN3 such as a polysilicon layer at the end of the annealing process. As described above, the amorphous silicon layer may be mixed in a part of the semiconductor layer CN3. In addition, as described above, the polycrystallization of the semiconductor layer CN3 may continuously progress by the subsequent annealing process.

Thereafter, as in the embodiment described above, a getter layer is formed at the upper end of the pillar PLr in the middle of formation, and the metal fragment NSf segregated at the lower end of the pillar PLr is removed.

Thus, the pillar PLr of the modification is formed.

According to the semiconductor memory device of the modification, effects similar to those of the embodiment described above are achieved.

In the embodiment described above, the metal-containing layer NS is formed in advance at the lower end of the memory hole MH, and the semiconductor layer CN4 outside the semiconductor layer CN2 is subjected to the metal-assisted annealing process. However, the method of the metal-assisted annealing process on the semiconductor layer CN4 of the embodiment described above is not limited to the method described above.

As an example, in a case where the semiconductor layer CN4 outside the semiconductor layer CN2 is crystallized as described in the embodiment, instead of the metal-containing layer NS at the lower end of the memory hole MH, the metal-containing layer NS formed at the upper end of the memory hole MH may be used as in the modification.

In this case, the semiconductor layer CN2 can be interposed in the semiconductor layer CN4 between the memory layer ME and the core layer CR, and the semiconductor layer CN2 can be formed also at the upper end of the semiconductor layer CN4 on the core layer CR side, which is not to be crystallized. As a result, it is possible to perform metal-assisted crystallization of the semiconductor layer CN4 on the memory layer ME side while crystallization of the semiconductor layer CN4 on the core layer CR side is prevented.

Further, in the embodiment and modification described above, the semiconductor memory device 1 includes the stacked body LM having a two-tier structure in which the two stacked bodies LMa and LMb are stacked vertically. However, the configuration of the stacked body is not limited to the two-tier structure, and may be one-tier structure or three-tier structure or more.

In the embodiment and modification described above, the pillars PL and PLr are connected to the source line SL on the side surfaces of the channel layers CN and CNr, but the present disclosure is not limited thereto. For example, the pillar may be configured to be connected to the source line at the lower end of the channel layer by removing the memory layer on the bottom surface of the pillar.

In the embodiment and modification described above, the peripheral circuit CBA is disposed above the stacked body LM. However, the peripheral circuit may be disposed below the stacked body, or may be disposed on the same layer as the stacked body. In a case where the peripheral circuit is disposed below the stacked body, the stacked body or the like can be formed directly above the semiconductor substrate on which the peripheral circuit is formed. In addition, in a case where the peripheral circuit is disposed on the same layer as the stacked body, the stacked body can be formed at a position different from the peripheral circuit on the semiconductor substrate on which the peripheral circuit is formed.

While certain embodiments have been described, these embodiments have been presented by way of example only, and are not intended to limit the scope of the present disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor memory device comprising:
a stacked body in which a plurality of conductive layers and a plurality of insulating layers are alternately stacked one by one; and
a pillar extending in the stacked body in a stacking direction of the stacked body, wherein
the pillar includes
a first semiconductor layer extending in the stacked body in the stacking direction, and
a second semiconductor layer that extends in the stacked body in the stacking direction and includes more grain boundaries than grain boundaries of the first semiconductor layer, and
an additive having a peak concentration at an interface between the first semiconductor layer and the second semiconductor layer is included.

2. The semiconductor memory device according to claim 1, wherein
the pillar includes a memory layer on an outer peripheral portion, and
the first semiconductor layer is disposed between the memory layer and the second semiconductor layer.

3. The semiconductor memory device according to claim 1, wherein
the pillar includes a memory layer on an outer peripheral portion, and
the second semiconductor layer is disposed between the memory layer and the first semiconductor layer.

4. The semiconductor memory device according to claim 1, wherein
the peak concentration of the additive is greater than 2×10²¹ atoms/cm³.

5. The semiconductor memory device according to claim 1, wherein
the additive is at least one selected from the group consisting of carbon, nitrogen, oxygen, and fluorine.

6. The semiconductor memory device according to claim 1, wherein
the additive is carbon.

7. The semiconductor memory device according to claim 1, wherein
the first semiconductor layer is a single crystal layer, and
the second semiconductor layer is a polycrystalline layer.

8. A method for manufacturing a semiconductor memory device, comprising:
forming a stacked body in which a plurality of first insulating layers and a plurality of second insulating layers are alternately stacked one by one;
forming a hole extending in the stacked body in a stacking direction of the stacked body; and
forming, in the hole, first and second semiconductor layers extending in the stacking direction of the stacked body, wherein
the formation of the first and second semiconductor layers includes
adding an additive so as to have a peak concentration at an interface between the first semiconductor layer and the second semiconductor layer to form the first and second semiconductor layers that are amorphous, and
crystallizing the first semiconductor layer that is amorphous by an annealing process with metal assist to form the first semiconductor layer that is crystalline.

9. The method for manufacturing a semiconductor memory device according to claim 8, wherein
the crystallization of the first semiconductor layer includes
inhibiting crystallization of the second semiconductor layer by the additive localized on the interface between the first semiconductor layer and the second semiconductor layer.

10. The method for manufacturing a semiconductor memory device according to claim 8, wherein
the formation of the first and second semiconductor layers includes
single-crystallizing the first semiconductor layer that is amorphous by the annealing process with the metal assist.

11. The method for manufacturing a semiconductor memory device according to claim 8, comprising
polycrystallizing the second semiconductor layer that is amorphous to form the second semiconductor layer that is polycrystalline,
by performing the annealing process without the metal assist on the second semiconductor layer at a time of the annealing process with the metal assist, or
by performing another annealing process after the annealing process with the metal assist.

12. The method for manufacturing a semiconductor memory device according to claim 8, further comprising
forming a memory layer on a side wall of the hole before the first and second semiconductor layers are formed, wherein
the formation of the first and second semiconductor layers includes
forming, in the hole, the first semiconductor layer covering the memory layer, and
forming, in the hole, the second semiconductor layer covering the first semiconductor layer.

13. The method for manufacturing a semiconductor memory device according to claim 8, further comprising
forming a memory layer on a side wall of the hole before the first and second semiconductor layers are formed, wherein
the formation of the first and second semiconductor layers includes
forming, in the hole, the second semiconductor layer covering the memory layer, and
forming, in the hole, the first semiconductor layer covering the second semiconductor layer.

14. The method for manufacturing a semiconductor memory device according to claim 8, wherein
the formation of the first and second semiconductor layers includes
adding the additive to the interface between the first and second semiconductor layer so that the peak concentration is greater than 2×10²¹ atoms/cm³.

15. The method for manufacturing a semiconductor memory device according to claim 8, wherein
the formation of the first and second semiconductor layers includes
adding at least one selected from the group consisting of carbon, nitrogen, oxygen, and fluorine as the additive to the interface between the first semiconductor layer and the second semiconductor layer.

16. The method for manufacturing a semiconductor memory device according to claim 8, wherein
the formation of the first and second semiconductor layers includes
adding carbon as the additive to the interface between the first semiconductor layer and the second semiconductor layer.
